(19) United States
(12) Patent Application Publication
(10) Pub. No.: US 2011/0068366 A1
(43) Pub. Date: Mar. 24, 2011

(54) Bi-directional SCR ESD device

(75) Inventor: Chih-Feng Huang, Jhubei City (TW)

(73) Assignee: Richtek Technology Corporation

(21) Appl. No.: 12/586,456

(22) Filed: Sep. 22, 2009

(51) Int. Cl. H01L 29/73

(52) U.S. Cl. 257/173; 257/E29.181

(57) ABSTRACT

The present invention discloses a bi-directional SCR ESD device, comprising: a substrate; a first well located in the substrate, which is floating and has a first conductivity type; a second well and a third well both located in the first well and both having a second conductivity type, the second well and the third well being separated from each other; a first high density doped region of the first conductivity type and a second high density doped region of the second conductivity type located in the second well; and a third high density doped region of the first conductivity type and a fourth high density doped region of the second conductivity type located in the third well.

### BACKGROUND OF THE INVENTION

1. Field of Invention

The present invention relates to a bi-directional silicon controlled rectifier (SCR) electro-static discharge (ESD) device; particularly, it relates to a bi-directional SCR ESD device which provides protection even when positive and negative terminals of a circuit are connected to wrong polarities or when a positive terminal of a circuit receives a negative voltage.

2. Description of Related Art

ESD devices are used in many integrated circuits to discharge high voltage received by external pins before the high voltage damages internal devices. One type of ESD devices uses an SCR. FIG. 1 shows such a conventional SCR ESD device, which includes: an N-type well 11 and a P-type well 21 located in a P-type substrate 100, a high density P+ doped region 13 and a high density N+ doped region 15 located in the N-type well 11, and a high density P+ doped region 23 and a high density N+ doped region 25 located in the P-type well 21. In this SCR ESD device, the P+ doped region 13, the N+ doped region 15, the N-type well 11, and the P-type well 21 constitute a PNP transistor; the N-type well 11, the P-type well 21, and the N+ doped region 25 constitute an NPN transistor. An external pad PAD is coupled to the P+ doped region 13 and the N+ doped region 15, and, an external grounding pad GND is coupled to the P+ doped region 23 and the N+ doped region 25. Thus, when the external pad PAD receives a high voltage, the SCR ESD device is triggered to conduct a current to the grounding pad GND.

However, in certain applications such as in a battery charger, a user often reversely connects the positive and negative terminals of the circuit to wrong polarities, that is, to connect the grounding pad GND to a positive voltage and the pad PAD to ground. Under such circumstance, the prior art ESD device will be damaged due to a high current caused by a forward biased diode.

Besides, the abovementioned prior art has the following drawback. When the external pad PAD receives a negative voltage, a junction diode formed by the high density N+ doped region 15, the N-type well 11, and the P-type substrate 100 will be forward biased and turned on, resulting in a current loss from the substrate 100 to the external pad PAD. The current loss consumes power, and furthermore it may create a latch-up effect, causing malfunctions of internal circuit devices. In general ESD design, it is not expected that a negative voltage will be applied to the external pad PAD. However, when the circuit is used to drive power transistor switches, a transient negative voltage may be applied to the external pad PAD due to the switching ringing of the power transistor switches.

In view of the foregoing, the present invention provides a bi-directional SCR ESD device, which can provide protection even when the connection pad PAD and the grounding pad GND are reversely connected to wrong polarities or when the pad PAD receives a negative voltage.

### SUMMARY OF THE INVENTION

An objective of the present invention is to provide a bi-directional SCR ESD device.

In order to achieve the foregoing objective, according to one perspective of the present invention, it provides an SCR ESD device, comprising: a substrate; a first well located in the substrate, which is floating and has a first conductivity type; a second well and a third well both located in the first well and both having a second conductivity type, the second well and the third well being separated from each other; a first high density doped region of the first conductivity type and a second high density doped region of the second conductivity type located in the second well; and a third high density doped region of the first conductivity type and a fourth high density doped region of the second conductivity type located in the third well.

In the bi-directional SCR ESD device mentioned above, in one embodiment, a high density doped region is formed at the junction area between the first well and the second or the third well. The high density doped region can be the first conductivity type or the second conductivity type. In another embodiment, a high density doped region of the first conductivity type is formed in the first well with a predetermined distance apart from the junction area between the first well and second well. Or in another embodiment, a high density doped region of the second conductivity type is formed in the second well with a predetermined distance apart from the junction area between the first well and second well. Or in another embodiment, a high density doped region of the second conductivity type is formed in the third well with a predetermined distance apart from the junction area between the first well and third well.

The objectives, technical details, features, and effects of the present invention will be better understood with regard to the detailed description of the embodiments below.

### BRIEF DESCRIPTION OF THE DRAWINGS

FIG. 1 is a cross-sectional diagram of a prior art SCR ESD device.

FIG. 2 to FIG. 7 show schematic cross-sectional diagrams of several embodiments of the present invention.

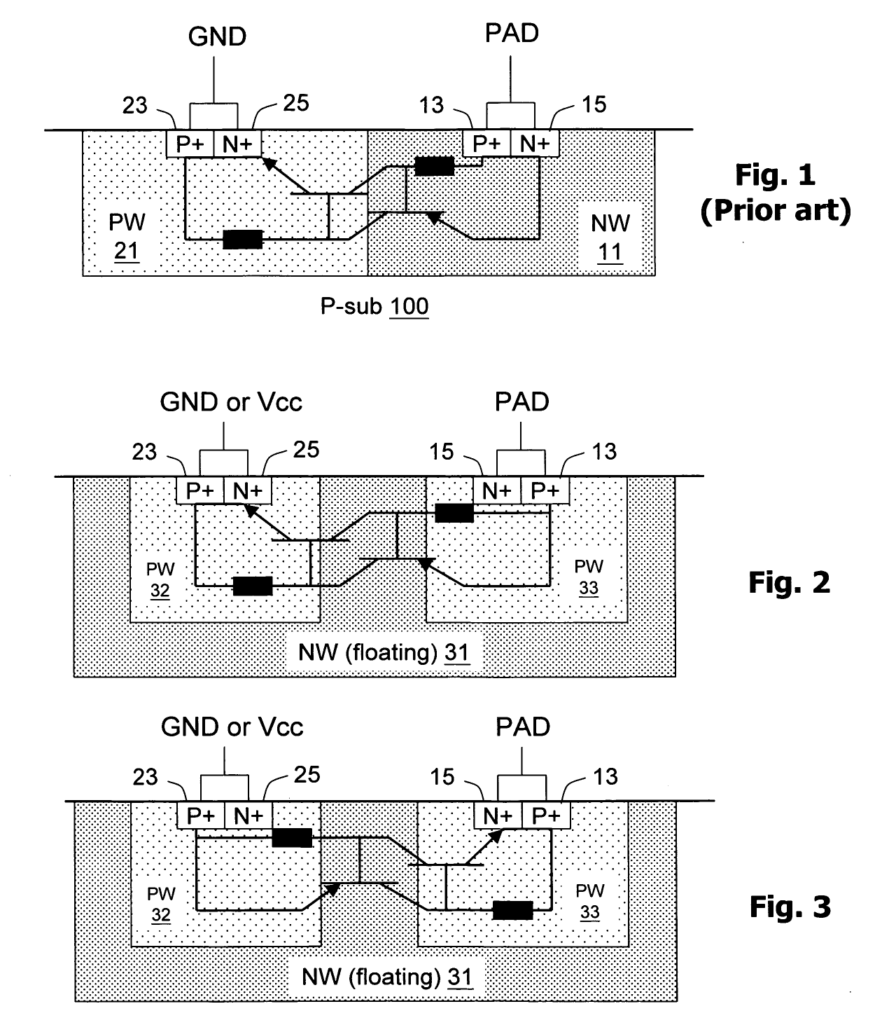

### DESCRIPTION OF THE PREFERRED EMBODIMENTS

The drawings as referred to throughout the description of the present invention are for illustration only, but not drawn according to actual scale.

Referring to FIG. 2 and FIG. 3, the first embodiment of the present invention is shown. In this embodiment, the N-type well 31 is located in the substrate but is floating, and two P-type wells 32 and 33 are formed in the N-type well 31. A high density P+ doped region 23 and a high density N+ doped region 25 are formed in the P-type well 32, and a high density P+ doped region 13 and a high density N+ doped region 15 are formed in the P-type well 33. As shown in FIG. 2, when the external pad PAD receives a high positive voltage, the PNPN SCR formed by the P+ region 13, P-type well 33, N-type well 31, P-type well 32, and N+ region 25 is triggered and provides a current path to discharge the high voltage on the external pad PAD. On the other hand, as FIG. 3 shows, when the grounding pad GND receives a high positive voltage, the PNPN SCR formed by the P+ region 23, P-type well 32, N-type well 31, P-type well 33, and N+ region 15 is triggered and provides another current path to discharge the high voltage on the grounding pad GND. Furthermore, if the external pad PAD or the grounding pad GND is connected to a negative voltage, the negative voltage does not adversely impact the circuit. Therefore, no matter how the external pad PAD and grounding pad GND are connected, the ESD device of the present invention can provide ESD function to protect the internal circuit safely.

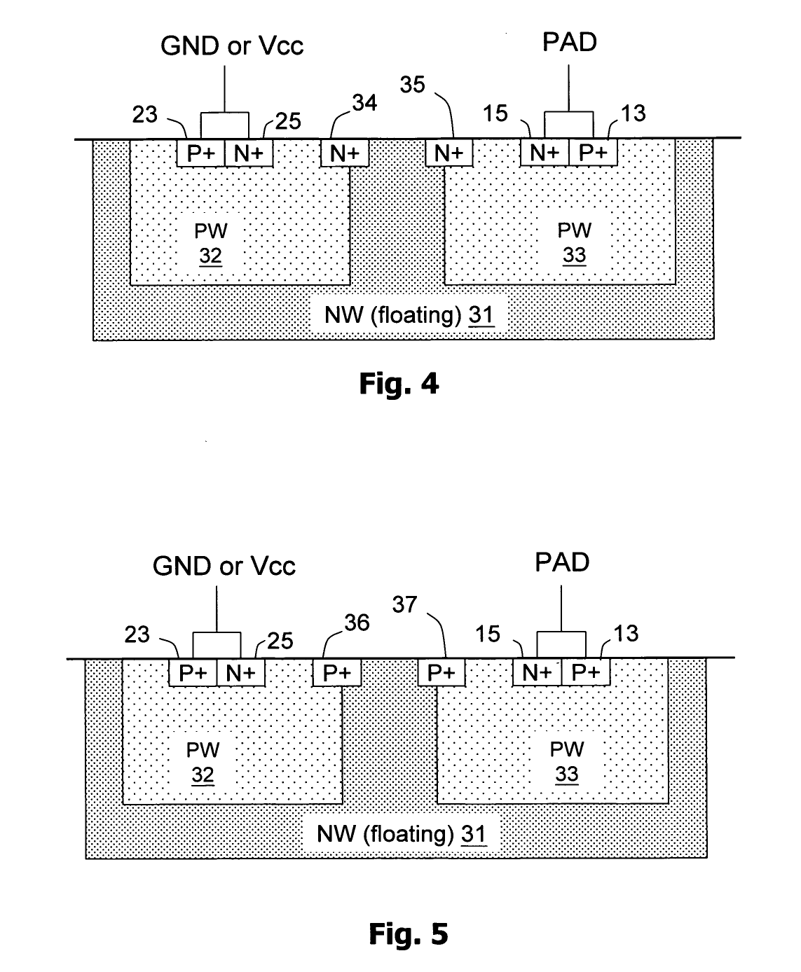

FIG. 4 shows another embodiment of the present invention. In this embodiment, two high density N+ doped regions 34 and 35 are formed at the junction areas between the N-type well 31 and the P-type well 32 and between the N-type well 31 and the P-type well 33, respectively. The purpose of the N+ doped regions 34 and 35 is to adjust the trigger voltage of the ESD device. More specifically, the breakdown voltages of the junction diodes formed by the N-type well 31 and the P-type wells 32 and 33 are high, for example, about 40V or so. If the N+ doped regions 34 and 35 are provided, by means of the junction formed by the N+ doped region 34 and the P-type wells 32, and the junction formed by the N+ doped region 35 and the P-type well 33, the breakdown voltages, can be effectively reduced to, e.g., about 12-15V or so; as a result, the SCR can be turned on at a lower voltage to trigger the ESD function.

FIG. 5 shows a similar embodiment to FIG. 4. Two high density P+ doped regions 36 and 37 are formed at the junction areas between the N-type well 31 and the P-type well 32, and between the N-type well 31 and the P-type well 33. The purpose of the P+ doped regions 36 and 37 is also for adjusting the trigger voltage of the ESD device. The junctions formed by the N-type well 31 and P+ doped regions 36 and 37 can also reduce the breakdown voltage, so as to trigger the ESD function earlier.

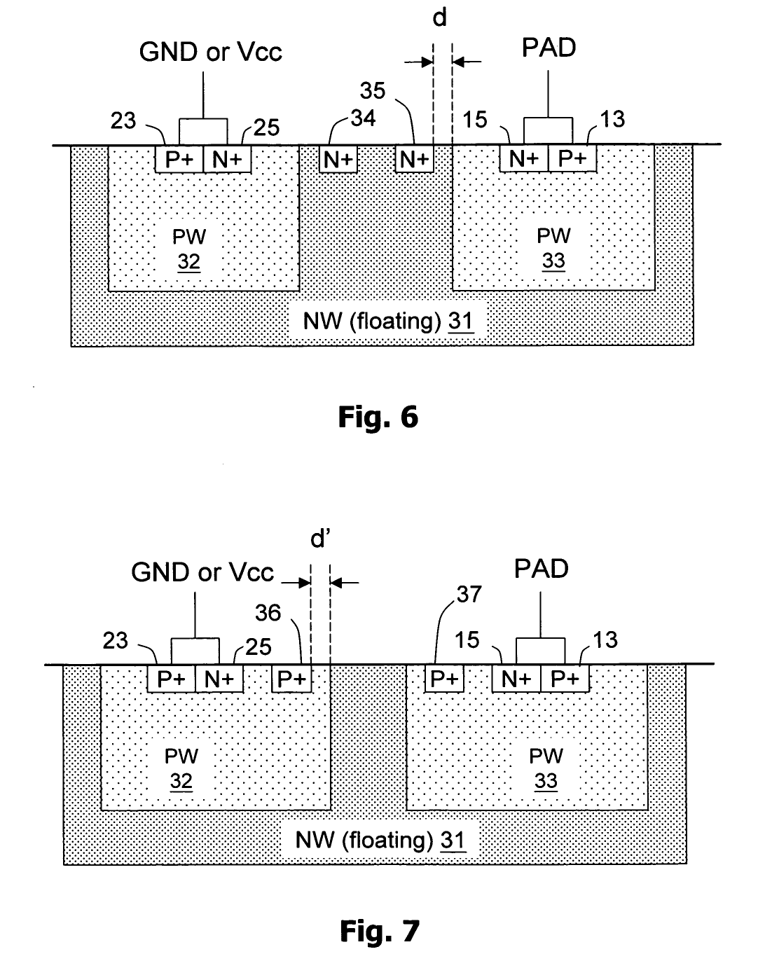

FIG. 6 shows another embodiment of the present invention. In this embodiment, the N+ doped regions 34 and 35 are not formed at the junction areas between the N-type well 31 and P-type wells 32 and 33, but rather at a predetermined distance d apart from the junction area. By adjusting the distance d, the trigger voltage of the ESD device can be adjusted to a range between the embodiments of FIG. 2 and FIG. 4.

FIG. 7 shows another embodiment of the present invention. In this embodiment, the P+ doped regions 36 and 37 are not formed at the junction areas between N-type well 31 and P-type wells 32 and 33, but rather at a predetermined distance d′ apart from the junction area. By adjusting the distance d′, the trigger voltage of the ESD device can be adjusted to a range between the embodiments of FIG. 2 and FIG. 5.

The present invention has been described in considerable detail with reference to certain preferred embodiments thereof. It should be understood that the description is for illustrative purpose, not for limiting the scope of the present invention. Those skilled in this art can readily conceive variations and modifications within the spirit of the present invention. For example, the N+ doped regions 34 and 35 or the P+ doped regions 36 and 37 are not necessarily formed symmetrically; only one of them can be formed without the other. As another example, in FIG. 6, the N+ doped regions 34 and 35 can be combined to one region. As yet another example, one of the N+ doped regions 34 and 35 and one of the P+ doped regions 36 and 37 can be both provided. In view of the foregoing, the spirit of the present invention should cover all such and other modifications and variations, which should be interpreted to fall within the scope of the following claims and their equivalents.

What is claimed is:

1. A bi-directional silicon controlled rectifier (SCR) electro-static discharge (ESD) device comprising:
a substrate;
a first well located in the substrate, which is floating and has a first conductivity type;
a second well and a third well both located in the first well and both having a second conductivity type, the second well and the third well being separated from each other;
a first high density doped region of the first conductivity type and a second high density doped region of the second conductivity type located in the second well; and
a third high density doped region of the first conductivity type and a fourth high density doped region of the second conductivity type located in the third well.

2. The bi-directional SCR ESD device of claim 1, wherein the first and second high density doped regions are coupled to a positive voltage, a negative voltage, or ground.

3. The bi-directional SCR ESD device of claim 1, wherein the third and fourth high density doped regions are coupled to a positive voltage, a negative voltage, or ground.

4. The bi-directional SCR ESD device of claim 1, further comprising a fifth high density doped region located at a junction area between the first and second wells.

5. The bi-directional SCR ESD device of claim 4, wherein the fifth high density doped region is the first or second conductivity type.

6. The bi-directional SCR ESD device of claim 1, further comprising a fifth high density doped region located at a junction area between the first and third wells.

7. The bi-directional SCR ESD device of claim 1, wherein the fifth high density doped region is the first or second conductivity type.

8. The bi-directional SCR ESD device of claim 1, further comprising a fifth high density doped region located in the first well and with a predetermined distance from a junction area between the first and second wells.

9. The bi-directional SCR ESD device of claim 8, wherein the fifth high density doped region is the first conductivity type.

10. The bi-directional SCR ESD device of claim 1, further comprising a fifth high density doped region located in the first well and with a predetermined distance from a junction area between the first and third wells.

11. The bi-directional SCR ESD device of claim 10, wherein the fifth high density doped region is the first conductivity type.

12. The bi-directional SCR ESD device of claim 1, further comprising a fifth high density doped region located in the second well and with a predetermined distance from a junction area between the first and second wells.

13. The bi-directional SCR ESD device of claim 12, wherein the fifth high density doped region is the second conductivity type.

14. The bi-directional SCR ESD device of claim 1, further comprising a fifth high density doped region located in the third well and with a predetermined distance from a junction area between the first and third wells.

15. The bi-directional SCR ESD device of claim 14, wherein the tenth high density doped region is the second conductivity type.

16. The isolated SCR ESD device of claim 1, wherein the first conductivity type is N-type and the second conductivity type is P-type.
